(19) United States
(12) Patent Application Publication
(10) Pub. No.: US 2015/0048497 A1
(43) Pub. Date: Feb. 19, 2015

(54) INTERPOSER WITH ELECTROSTATIC DISCHARGE PROTECTION

(71) Applicant: QUALCOMM Incorporated, San Diego, CA (US)

(72) Inventors: Brian Matthew Henderson, Escondido, CA (US); Shiqun Gu, San Diego, CA (US); Urmi Ray, Ramona, CA (US)

(73) Assignee: QUALCOMM Incorporated, San Diego, CA (US)

(21) Appl. No.: 13/968,708

(22) Filed: Aug. 16, 2013

(51) Int. Cl. H01L 23/498; H01L 23/522; H01L 21/768

(52) U.S. Cl. CPC H01L 23/49811; H01L 21/76802; H01L 23/5226
USPC 257/737; 438/637; 257/774

(57) ABSTRACT

A photovoltaic (PV) substrate includes a grooved die-facing surface to form a channel for a bypass diode. The die-facing surface supports a screen-printed metal interconnect layer to form a first terminal for the bypass diode.

### TECHNICAL FIELD

This application relates to an interposer with electrostatic discharge protection.

### BACKGROUND

As I/O density has increased in modern integrated circuits, the packaging of high-density circuits using interposers has increased in popularity. For example, FIG. 1A shows a “2.5D” interposer package 100 that includes high-density I/O integrated circuits or dies 105, 110, and 115 mounted side-by-side on an interposer 120. Alternatively, if the dies are stacked, an interposer package may be referred to as a “3D” package. Dies 105, 110, and 115 mount to interposer 120 through interconnects such as micro bumps 125 on a die-facing surface of interposer 120. Because an interposer 120 comprises a silicon semiconductor substrate (or glass), it may accommodate a fine I/O pitch for micro bumps 125. Interposer 120 includes a plurality of through substrate vias (TSVs) 130 to couple micro bumps 125 to solder balls 135 on an opposing back surface of interposer 120. For illustration clarity, TSVs 130 are illustrated coupling only to die 110 but additional through substrate vias (not illustrated) would couple to the remaining dies. Bottom balls 135 mount to, for example, an organic substrate (not illustrated). Unlike interposer 120, an organic substrate cannot accommodate a very fine pitch. Interposer 120 may thus serve to accommodate a fine I/O pitch for dies 105, 110, and 115 to the coarser pitch for an organic substrate.

Regardless of the dimensionality of an interposer package, its integrated circuits should include electrostatic discharge (ESD) protection. Electrostatic discharge protection commonly involves the use of two bypass diodes because integrated circuits need protection from excessive positive charge as well as excessive negative charge. Dies 105, 110, and 115 would include bypass diodes for each I/O port coupled to a corresponding bump 125. As shown in FIG. 1B for a die's general purpose I/O (GPM) circuit 150, a first bypass diode 155 couples between the GPIO's input/output port or pad 160 and a power supply rail 165. Should pad 160 be subjected to excessive positive charge from an ESD event, first bypass diode 155 becomes forward biased and conducts the excessive charge into power supply (VDD) rail 165 to protect the core circuitry on the die. Similarly, a second bypass diode 170 couples between pad 160 and ground. If pad 160 is subjected to excessive negative charge from an ESD event, second bypass diode 170 becomes forward biased and conducts the excessive charge into ground (VSS) to protect the integrated circuit's core. Second bypass diode 170 may thus also be denoted as the “VSS-side” bypass diode whereas first bypass diode 155 may be denoted as a “VDD-side” bypass diode.

The bypass diodes require a relatively large amount of die space for their implementation and thus increase integrated circuit cost. To address this issue, interposers have been developed that include integrated diodes to reduce the ESD die space demands. But these conventional ESD-diode-integrated interposers require photolithographic steps during their manufacture and are thus relatively costly. Although the die area demands are reduced, the overall cost for an interposer package including a conventional ESD-diode-integrated interposer is still expensive given the increased costs for the interposer. Accordingly, there is a need in the art for interposer packaging of integrated circuits with reduced manufacturing costs.

### SUMMARY

An interposer comprising a photovoltaic (PV) substrate of a first conductivity type includes bypass diodes for ESD protection of circuitry on an associated die. The PV substrate includes an active surface having doped regions of a second conductivity type that is grooved to form first contact regions for the bypass diodes. An opposing surface for the PV substrate may also be grooved to form second contact regions for the diodes. A screen-printed metal interconnect layer on the active surface couples to the diode contact regions. A die attached to the interposer couples to the screen-printed metal interconnect layer though interconnections such as micro bumps. The opposing surface of the PV substrate may also include a screen-printed metal interconnect layer. In embodiments in which the PV substrate incorporates through silicon vias (TSVs), the screen-printing of the metal interconnect layers also plates the TSVs with metal.

The PV substrate may include a doped surface layer prior to the grooving of the active surface. Alternatively, the PV substrate may have no doped surface layer prior to the grooving of the active surface. In embodiments in which the bulk PV substrate has no preexisting doped surface layer, the active surface of the PV substrate is doped after the grooving step to form diffusion regions in portions of the PV substrate facing the grooves.

### BRIEF DESCRIPTION OF THE DRAWINGS

FIG. 1A is a cross-sectional view of an interposer package in accordance with an embodiment of the disclosure.

FIG. 1B is a schematic diagram of the ESD diodes within a general purpose I/O (GPIO) circuit for a conventional die.

FIG. 2 is a schematic diagram of a GPIO circuit for a die in an interposer package that incorporates one of the ESD diodes in accordance with an embodiment of the disclosure.

FIG. 3A is a cross-sectional view of a doped photovoltaic (PV) substrate.

FIG. 3B is a cross-sectional view of the PV substrate of FIG. 3A after deposition of an insulating dielectric layer.

FIG. 3C is a cross-sectional view of the PV substrate of FIG. 3B after a laser grooving step for the formation of diode contact regions.

FIG. 3D is a cross-sectional view of the PV substrate of FIG. 3C after a laser grooving step for diode isolation.

FIG. 4A is a cross-sectional view of a bulk PV substrate.

FIG. 4B is a cross-sectional view of the PV substrate of FIG. 4A after deposition of an insulating dielectric layer.

FIG. 4C is a cross-sectional view of the PV substrate of FIG. 4B after a laser grooving step for the formation of diode contact regions.

FIG. 4D is a cross-sectional view of the PV substrate of FIG. 4C after a doping step.

FIG. 5A is a cross-sectional view of the PV substrate of FIG. 4D after application of a screen-printed metal interconnect layer on a first side of the PV substrate.

FIG. 5B is a cross-sectional view of the PV substrate of FIG. 5A after application of a screen-printed metal interconnect layer on an opposing second side of the PV substrate.

FIG. 5C is a cross-sectional view of the PV substrate of FIG. 5B after bump formation.

FIG. 5D is a cross-sectional view of a PV substrate similar to that of FIG. 5B but without through silicon vias after bump formation.

FIG. 6 is a flowchart for a method of manufacture for an interposer in accordance with an embodiment of the disclosure.

FIG. 7 illustrates some example electronic systems incorporating an interposer package in accordance with an embodiment of the disclosure.

### DETAILED DESCRIPTION

To provide a practical solution to the need for reducing die space demands for ESD bypass diodes, an ESD-diode-integrated interposer comprising a photovoltaic (PV) substrate of a first conductivity type is provided. The PV substrate includes an active surface that is grooved to form first contact regions (which may also be denoted as channels) for the bypass diodes. The active surface may also be denoted as a die-facing surface. An opposing back surface for the PV substrate may also be grooved to form second contact regions for the bypass diodes. Metal interconnect layers couple to these first and second contact regions to form first and second terminals, respectively, for the bypass diodes. In alternative embodiments, both the first and second terminals for a bypass diode may be located on the active surface of the PV substrate. In such embodiments, one groove on the die-facing surface of the PV substrate forms a first contact region for a bypass diode whereas a second groove on the die-facing surface of the PV substrate forms a second contact region for the bypass diode. In embodiments in which the PV substrate includes through silicon vias (TSVs), the screen-printed metal interconnect layers also plate the TSVs with metal interconnect.

Regardless of whether the second contact regions for the bypass diode are located on the die-facing surface or on the opposing back surface of the PV substrate, the metal interconnect layers are screen-printed metal interconnect layers. This is quite advantageous in that neither the screen printing of the metal interconnect layers nor the grooving of the PV substrate requires any photolithographic steps. In addition, no photolithography is required if a doping step is required after the grooving of the die-facing surface. Manufacture of the resulting interposer is thus relatively inexpensive as compared to the manufacture of conventional ESD-diode-integrated interposers, which requires expensive photolithographic steps. Moreover, the PV substrate itself is relatively low cost. In this fashion, a very low cost solution is provided that integrates ESD diodes onto the interposer instead of requiring die space on the associated die(s) that includes a remaining portion of the ESD circuitry and diodes.

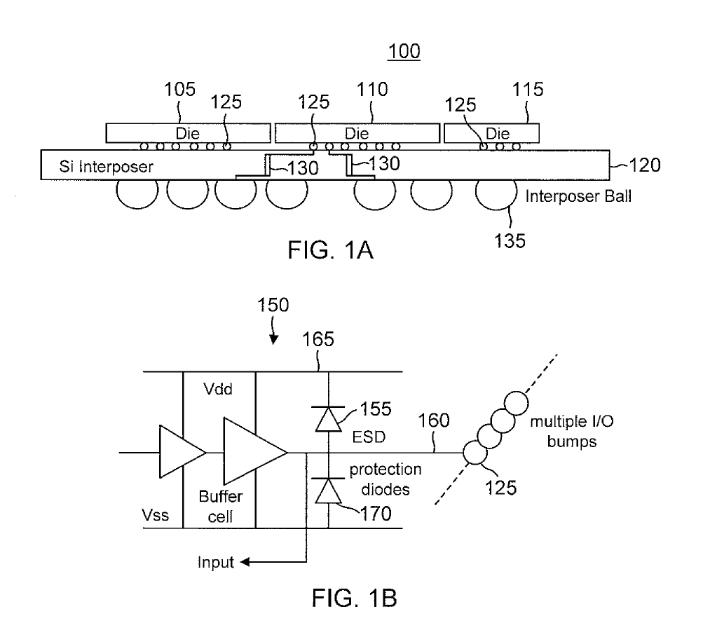

Although the manufacture of the ESD-diode-integrated interposers disclosed herein is dramatically less expensive than the manufacture of conventional ESD-diode-integrated interposers, the attachment of die(s) to the disclosed ESD-diode-integrated interposers may be performed in a conventional fashion. In that regard, interposer package 100 of FIG. 1A is generic as to whether interposer 120 is conventional or as disclosed herein.

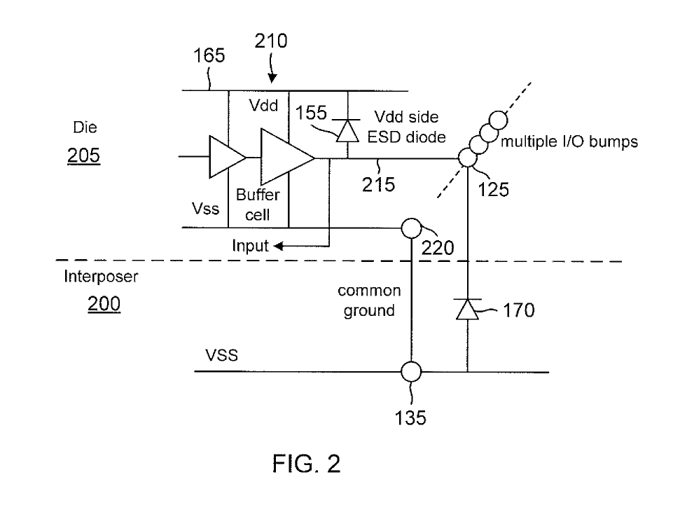

An example ESD-diode integrated interposer 200 and associated die 205 is shown in FIG. 2. Die 205 includes a general purpose input/output (GPIO) circuit 210 having an I/O pad 215 coupled to an interconnect such as a micro bump 125. In contrast to conventional GPIO circuit 150 of FIG. 1B, GPIO circuit 210 includes only VDD-side bypass diode 155 and does not include a VSS-side bypass diode 170. Instead, a VSS-side bypass diode 170 is integrated into interposer 200. In interposer 200, VSS-side bypass diode 170 couples between ground (VSS) and micro bump 125 that couples to input pad 215 for die 205. In this fashion, GPIO circuit 210 is much denser as it no longer needs to reserve die space for VSS-side bypass diode 170. Interposer 200 comprises a PV substrate having a configuration in various embodiments that may be better understood with regard to the following discussion of example manufacturing methods for these embodiments.

### Example Methods of Manufacture

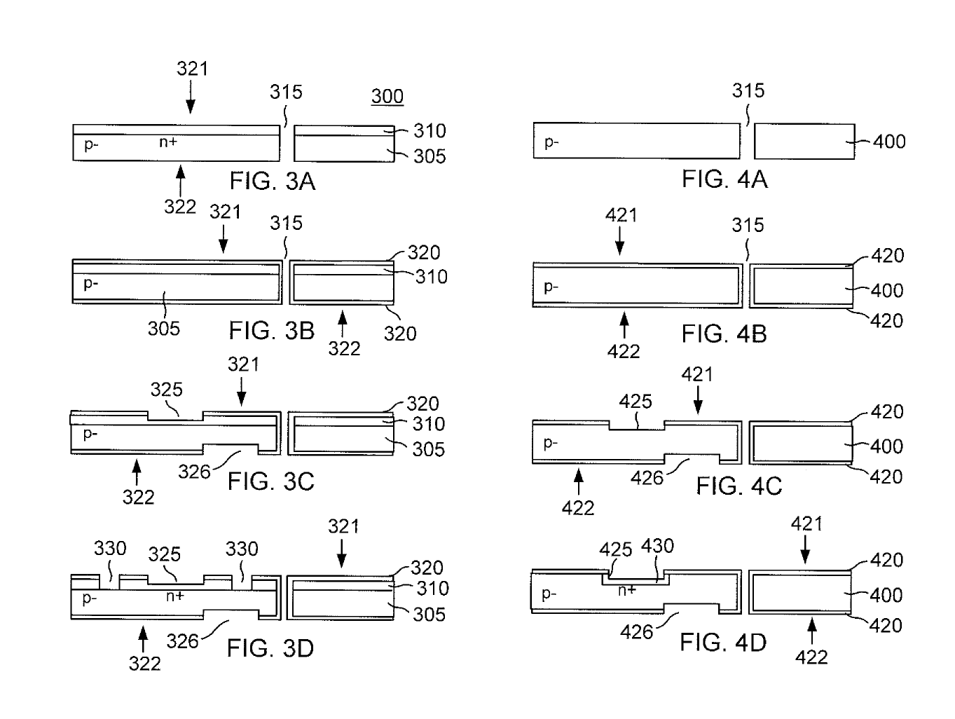

The PV substrate for the ESD-diode-integrated interposer embodiments disclosed herein may include a pre-existing n+ doped layer or may instead be doped during manufacture to include the n+ doped diffusion regions for forming a p-n junction to implement VSS-side diode 170 discussed with regard to FIG. 2. FIGS. 3A through FIGS. 3D show various manufacturing stages for an ESD-diode-integrated interposer in which the initial PV substrate includes a pre-existing n+ doped layer. Similarly, FIGS. 4A through 4D show analogous manufacturing stages for an ESD-diode-integrated interposer in which the initial PV substrate does not include a pre-existing n+ doped layer. The pre-existing n+ doped layer embodiment will be discussed first.

As shown in FIG. 3A, a bulk p− doped PV substrate 305 includes a n+ doped diffusion region that foul's a surface layer 310 on what will be a die-facing surface 321 on the resulting ESD-diode-integrated interposer. In contrast, an opposing back surface 322 of PV substrate 322 is not doped with a surface layer. The p-n junction formed by n+ surface layer 310 on PV substrate 305 may be adapted to form the VSS-side bypass diode 170 of FIG. 2 as follows. A laser or etching process may be used to faun a via 315 through n+ doped surface layer 310 and substrate 305 (to be used subsequently to form a through silicon via (TSV)). As will be discussed further below, alternative embodiments would not include TSVs.

After formation of via 315, the resulting structure may then be oxidized to form an insulating layer 320 over n+ doped surface layer 310 on die-facing surface 321 of PV substrate 305 as well as over opposing back surface 322 of PV substrate 305 as shown in FIG. 3B. In addition, insulating layer 320 lines via 315. In alternative embodiments, a dielectric deposition process such as sputtering may be used to form insulating layer 320. Insulating layer 320 over die-facing surface 321 may also be denoted as a first insulating layer whereas insulating layer 320 over back surface 322 may be denoted as a second insulating layer.

After formation of insulating layers 320, the die-facing surface 321 and opposing back surface 322 may both be laser grooved as shown in FIG. 3C to form contacts 325 and 326 (which may also be designated as channels) for the desired VSS-side diodes. For die-facing surface 321, a laser-grooved channel 325 extends through insulating layer 320 and only partially into n+ doped surface layer 310 so that an ensuing interconnect to channel 325 does not short through to PV substrate 305. For the opposing back surface 322 of substrate 305, a channel 326 extends through insulating layer 320 and partially into PV substrate 305. Each channel 325 and 336 extends substantially the same depth into their respective surfaces of PV substrate 305 although different depths may be used in alternative embodiments. Note that laser grooving involves no photolithography and thus is quite economical.

As will be discussed further below, a metal interconnect layer fills each channel 325 and 326 so that a VSS-side diode 170 may be formed between them (FIG. 2). But note that die 205 of FIG. 2 may include various GPIOs 210, each requiring bypass diodes for its pad 215. For illustration clarity, FIG. 3C shows just a pair of channels 325 and 326 to form one bypass diode but it will be appreciated that other pairs channels may be implemented in this fashion to form additional bypass diodes but are not shown for illustration clarity. To form separate VSS-side diodes 170 for each pad 215 (and corresponding bump 125) shown in FIG. 2, channel 325 in n+ doped surface layer 310 may be isolated from other channels (not shown) by forming laser-grooved isolation regions 330 as shown in FIG. 3D. In contrast to groove 325, isolation regions have a depth that extends through insulation layer 320 and n+ doped surface layer 310. Note that FIG. 3D is a cross-sectional view in that isolation regions 330 form a continuous circumferential structure that surrounds channel 325 so as to electrically isolate the underlying portion of n+doped surface layer 320 from the portions used to form other VSS-side diodes 170. Since channels 326 on the opposing surface of substrate 305 couple to a common ground VSS as discussed with regard to FIG. 2, there is no need to electrically isolate those back side channels. The final manufacturing steps are discussed further below. An embodiment in which the bulk PV substrate does not include a pre-existing n+ doped surface layer will now be discussed.

As shown in FIG. 4A, an alternative embodiment begins with a bulk p-doped PV silicon substrate 400 that does not include a pre-existing n-type surface layer. A laser or etching process may be used to form a via 315 in PV substrate 400 analogously as discussed with regard to PV substrate 305.

After formation of via 315, PV substrate 400 may then be oxidized as shown in FIG. 4B to faun an insulating layer 420 over what will be a die-facing surface 421 for PV substrate 400 as well over an opposing back surface 422. Insulating layer 420 also lines via 315. Alternatively, a dielectric may be deposited to form insulating layer 420 such as through a sputtering process.

To provide contacts for the resulting VSS-side diodes, laser-grooved channels 425 may then be formed through insulating layer 420 on die-facing surface 421 and into substrate PV 400 as shown in FIG. 4C. Similarly, the manufacturing processing includes a step of laser grooving channels 426 through insulating layer 420 on the opposing back surface 422 and into PV substrate 400.

The die-facing surface 421 may then be doped using, for example, POCL₃ or implanting techniques to form an n+doped diffusion region 430 in channel 425 as shown in FIG. 4D. Note that the patterned insulating layer 420 formed on die-facing surface 421 after formation of channel 425 acts as a mask such that diffusion region 430 is formed only in channel 425. In this fashion, no expensive and cumbersome photolithographic steps are necessary to form diffusion regions 430 for the resulting bypass diodes. Although the formation of an ESD-diode-integrated interposer using PV substrate 400 requires a doping step that is unnecessary if PV substrate 305 is used as the initial PV substrate, note that no isolation regions are needed. In contrast, manufacture of an ESD-diode-integrated interposer using PV substrate 305 requires isolation regions 330 because n+ doped surface layer 315 would otherwise be electrically coupled from diode to diode. As compared to n+ doped surface layer 315, diffusion region 430 has a lateral extent approximately the same as the lateral extent of channel 425. In contrast, n+ doped surface layer 315 extends across the lateral extent of die-facing surface 321 of PV substrate 305.

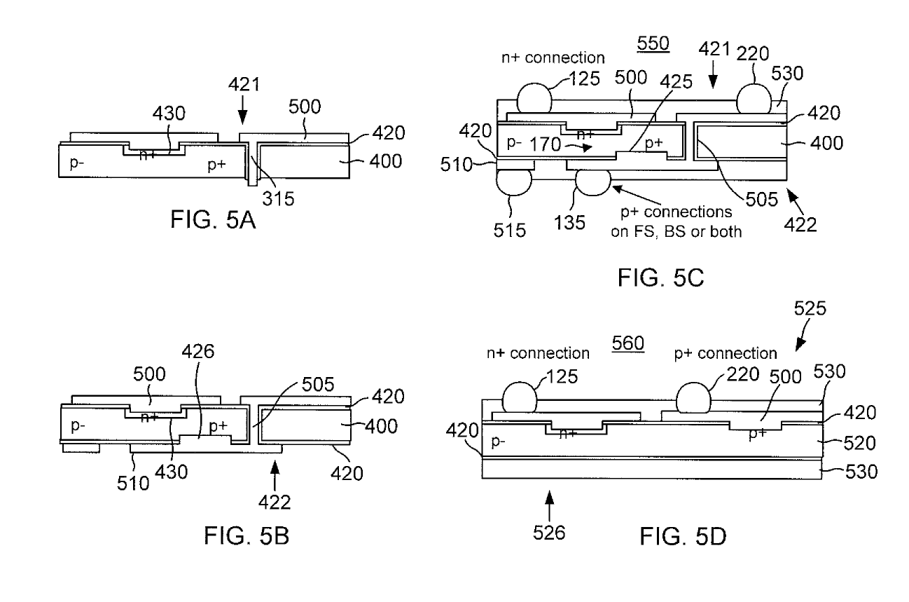

The remaining manufacturing steps are common to both the use of a PV substrate 305 including a pre-existing n+ doped surface layer 310 as discussed with regard to FIGS. 3A through 3D and to the use of a plain bulk PV substrate 400 as discussed with regard to FIGS. 4A through 4D. For illustration purposes, however, it will be assumed that the implanted PV substrate 400 from FIG. 4D is used in the final manufacturing steps as follows. As shown in FIG. 5A, the die-facing surface 421 of implanted PV substrate 400 may be screen printed with metal paste to form patterned metal interconnect layer 500. Metal interconnect layer 500 is patterned through the screen printing to form an isolated first terminal on n+ doped diffusion region 430. In addition, the application of metal interconnect layer 500 also metal plates via 315.

Another metal interconnect layer 510 may then be screen printed on opposing back surface 422 for implanted PV substrate 400 using metal paste as shown in FIG. 5B. Metal interconnect layer 510 forms a p+ ohmic contact in back side laser-grooved channel 426 and also completes a TSV 505 in what was via 315 (shown in FIG. 5A).

Suitable interconnects such as micro bumps 125 and balls 135 as discussed with regard to FIG. 1A may then be deposited on surfaces 421 and 422, respectively, as shown in FIG. 5C. In addition, passivation or solder resist layers 530 may be applied to both substrate surfaces to complete ESD-integrated interposer 550. Interposer 550 may then be integrated with one or more dies such as dies 105, 110, and 115 to form a completed die package 100 as discussed with regard to interposer 120 of FIG. 1A.

Metal interconnect layer 500 may also be denoted as a first metal interconnect layer 500 whereas metal interconnect layer 510 may be denoted as a second metal interconnect layer 510. First metal interconnect layer 500 forms a first terminal for VS S-side bypass diode 170 whereas second metal interconnect layer 510 forms a second terminal for VSS-side bypass diode 170.

Referring back to FIG. 2, a micro bump 220 serves as a common ground (VSS) connection for GPIO circuit 210. In contrast, the I/O for GPIO circuit 210 is carried on micro-bump 125. Another micro bump 125 serves as a power connection (not illustrated) to power rail 165. In that regard, each GPIO circuit 210 would couple to at least three micro-bumps: one for the common ground, one for its I/O signaling, and one for receiving the power supply voltage. As shown in FIG. 5C, micro bump 220 is also deposited in conjunction with micro bumps 125 and balls 135. TSV 505 is thus coupling back side ball 135 to micro bump 220 (note that balls 135 and micro bumps 220 and 125 are not drawn to scale in that balls 135 are typically significantly than micro bumps 220 and 125) to form a ground connection for a GPIO circuit on an associated die (not illustrated). TSV 505 thus serves in one embodiment as a means for coupling ground from back side ball 135 through PV substrate 400 to micro bump 220 Another TSV (not illustrated) would thus be used to couple micro-bump 125 to a ball 515 to carry the I/O signaling for the GPIO circuit on the associated die. As shown in FIG. 5B and 5C, metal interconnect layer 510 is patterned by the stencil (not illustrated) used in the screen printing application process to isolate ball 515 from other signals and from ground/power. During a normal mode of operation, ball 135 serves as ground for GPIO 210 of FIG. 2. But should GPIO 210 be subjected to excessive negative charge from an ESD event, VSS-side bypass diode 170 that results from the p-n junction between n+ doped diffusion region 430 and the p-doped substrate 400 conducts this excessive negative charge into ground through ball 135.

In an alternative embodiment shown in FIG. 5D, a bulk p− doped PV substrate 520 that does not include any vias may have its die-facing surface 525 processed to include insulating layer 420 and n+ doped diffusion region 430 in an analogous fashion as discussed with regard to PV substrate 400. But an opposing back surface 526 is not grooved in that the analog of groove 426 is formed on die-facing surface 525. Metal interconnect layer 500 on die-facing surface 525 is pattered to isolate the diode grooves. Micro bump 220 couples to the p+ diode groove whereas micro bump 125 couples to the n+ diode groove. An opposing back surface 526 to PV substrate 520 needs no metal interconnect layer because of the lack of TSVs (and back side diode contacts) in this embodiment. Application of passivation or insulating layers 530 completes a TSV-less ESD-diode-integrated interposer 560.

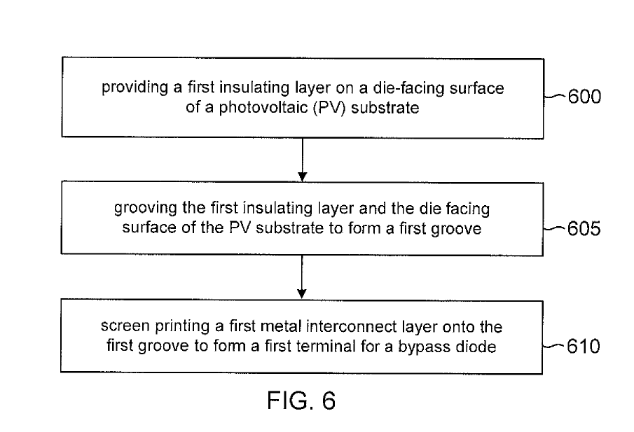

The manufacturing process discussed with regard to FIGS. 3A through 5D is summarized in a flow chart in FIG. 6. The process begins with a step 600 of providing a first insulating layer on a die-facing surface of a photovoltaic (PV) substrate. The process continues with a step 605 of grooving the first insulating layer on the die-facing surface of the PV substrate to faun a first groove for a bypass diode. Finally, the process includes a step 610 of screen printing a first metal interconnect layer onto the first groove to form a first terminal for the bypass diode. Note that such a screen printing step is generic to the embodiments disclosed herein. If this screen printing step also formed a second terminal for the bypass diode, the process would apply to a TSV-less ESD-diode-integrated interposer. If another screen printing step on the opposing back surface of the PV substrate is required, the process would apply to an ESD-diode-integrated interposer that includes TSVs (regardless of whether the bulk PV substrate included a pre-existing n+ doped surface layer or required doping after grooving of the insulating layer to form an n+ doped diffusion region).

### Example Electronic Systems

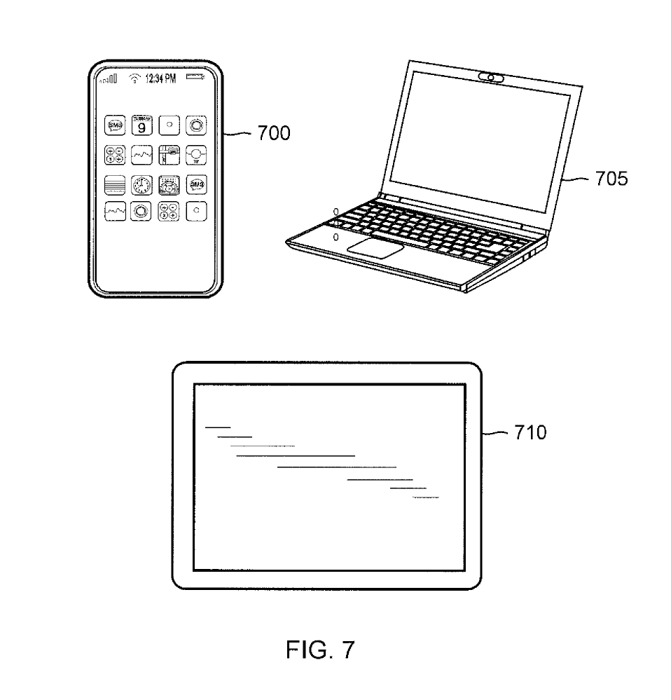

Die packages formed using a ESD-diode-integrated interposer as disclosed herein may be incorporated into a wide variety of electronic systems. For example, as shown in FIG. 7, a cell phone 700, a laptop 705, and a tablet PC 710 may all include a die package constructed in accordance with the disclosure. Other exemplary electronic systems such as a music player, a video player, a communication device, and a personal computer may also be configured with die packages constructed in accordance with the disclosure.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. An interposer, comprising:
a photovoltaic (PV) substrate of a first conductivity type, the PV substrate including a die-facing surface and a diffusion region of a second conductivity type;
a first insulating layer on the die-facing surface;
a first groove configured to extend through the first insulating layer and into the diffusion region; and
a first metal interconnect layer configured to fill the first groove to form a first terminal for a bypass diode.

2. The interposer of claim 1, further comprising:
a second insulating layer on an opposing back surface of the PV substrate;
a second groove configured to extend through the second insulating layer and into the opposing back surface of the PV substrate; and
a second metal interconnect layer configured to fill the first groove to form a second terminal for the bypass diode.

3. The interposer of claim 1, further comprising a through substrate via configured to extend through the PV substrate from the first metal interconnect layer to the second metal interconnect layer.

4. The interposer of claim 3, wherein the diffusion region is part of a surface layer configured to extend across the die-facing surface of the PV substrate.

5. The interposer of claim 3, wherein the diffusion region has a lateral extent approximately equal to a lateral extent of the first groove.

6. The interposer of claim 4, further comprising an isolation groove configured to extend through the first insulating layer and through the surface layer to electrically isolate the diffusion region from a remainder of the surface layer.

7. The interposer of claim 1, wherein the first conductivity type is p− and wherein the second conductivity type is n+.

8. The interposer of claim 2, wherein the first metal interconnect layer is a first screen-printed metal interconnect layer, and wherein the second metal interconnect layer is a second screen-printed metal interconnect layer.

9. The interposer of claim 8, further comprising a micro bump coupled to the first screen-printed metal interconnect layer and a ball coupled to the second screen-printed metal interconnect layer.

10. The interposer of claim 9, further comprising a die attached to the interposer, wherein the die includes a pad coupled to the micro bump.

11. The interposer and die of claim 10, wherein the interposer and die is incorporated into at least one of a cellphone, a laptop, a tablet, a music player, a communication device, a computer, and a video player.

12. A method, comprising
providing a first insulating layer on a die-facing surface of a photovoltaic (PV) substrate;
grooving the first insulating layer and the die-facing surface of the PV substrate to form a first groove; and
screen printing a first metal interconnect layer onto the first groove to form a first terminal for a bypass diode.

13. The method of claim 12, wherein forming the first insulating layer comprises oxidizing the die-facing surface of the PV substrate.

14. The method of claim 12, wherein forming the first insulating layer comprises depositing a dielectric onto the die-facing surface of the PV substrate.

15. The method of claim 12, further comprising:
providing a second insulating layer on an opposing back surface of the PV substrate;
grooving the second insulating layer and the opposing back surface of the PV substrate to form a second groove; and
screen printing a second metal interconnect layer onto the second groove to form a second terminal for the bypass diode.

16. The method of claim 12, further comprising: doping the die-facing surface of the PV substrate to faun a diffusion region in a portion of the PV substrate facing the first groove.

17. The method of claim 12, wherein the PV substrate includes a doped surface layer on the die-facing surface such that forming the first insulating layer comprises forming the first surface layer on the doped surface layer, and wherein grooving the die-facing surface of the PV substrate to form the first groove comprises grooving the doped surface layer.

18. An interposer, comprising:
a photovoltaic (PV) substrate of a first conductivity type, the PV substrate including a die-facing surface and a diffusion region of a second conductivity;
a first insulating layer on the die-facing surface;
a first groove configured to extend through the first insulating layer and into the diffusion region;
a first metal interconnect layer configured to fill the first groove to form a first terminal for a bypass diode; and
means for coupling ground from an opposing back surface of the PV substrate to the first metal interconnect layer.

19. The interposer of claim 18, wherein the means comprises a through silicon via.

20. The interposer of claim 18, wherein the first conductivity type is p− and the second conductivity type is n+.
